(19) United States
(12) Patent Application Publication
(10) Pub. No.: US 2005/0161074 A1
(43) Pub. Date: Jul. 28, 2005

(54) Photovoltaic module mounting unit and system

(76) Inventors: Paul Garvison, Frederick, MD (US); Donald B. Warfield, Woodbine, MD (US)

Correspondence Address: BP America Inc.;Docket Clerk, BP Legal, M.C. 5East, 4101 Winfield Road, Warrenville, IL, 60555, US

(21) Appl. No.: 11/011,674

(22) Filed: Dec. 14, 2004

Related U.S. Application Data
(60) Provisional application No. 60/529,799, filed on Dec. 16, 2003.

(51) Int. Cl. H01L 31/00

(52) U.S. Cl. 136/246; 136/251; 136/259; 136/256

(57) ABSTRACT

A photovoltaic unit suitable for installing on a support structure comprising a photovoltaic module having a light receiving top side, and a bottom side opposite the top side, and a support substrate attached to the bottom side of the module, the support substrate comprising a plurality of ridges and at least one trough.

This application claims the benefit of Provisional Patent Application No. 60/529,799 filed on Dec. 16, 2003.

### FIELD OF THE INVENTION

The present invention relates to mounting photovoltaic modules on a structure such as a building roof. The present invention also relates to photovoltaic module units for mounting photovoltaic modules, where the unit is structurally sound and protects the photovoltaic module and provides for easy and rapid installation of the module on a structure such as a building roof. This invention also relates to a photovoltaic module unit where the temperature of the mounted module can be regulated and, if desired, thermal energy, in addition to electrical energy, can be recovered from the mounted module.

### BACKGROUND OF THE INVENTION

In recent years, considerable advances have been made in using photovoltaic modules and other photovoltaic devices to directly convert solar and other light energy into useful electrical energy. Typically, a plurality of photovoltaic cells are encased or sandwiched between a transparent first sheet (e.g. glass, plastic, etc.) and a transparent or opaque back sheet, to form flat, rectangular-shaped modules, sometimes also called “laminates”. These modules are shipped to a site where they are used individually or, more typically, are assembled into an array onto the roof of a building or onto some other structure where the modules will be exposed to the sun. In order to make use of the electric current generated by the solar modules each mounted module is typically electrically connected to another module using electrical wiring, and the modules are connected, again using electrical wiring, to some central point where the electrical current is made available for transmission to one or more apparatus or system which uses the solar generated electrical current.

Many solar modules are constructed using glass, or other rigid or breakable substrates or sheets. Handling such modules during, for example, shipping and installation, has to be done with care to avoid breaking or otherwise damaging the modules. It would, therefore, be desirable to have a photovoltaic module unit where the photovoltaic module in the unit is less susceptible to breakage or damage. Certain photovoltaic modules, and particularly modules comprising crystalline or multicrystalline wafer components, operate more efficiently in specific temperature ranges. If, for example, the temperature of the module exceeds the upper limits of such range, efficiency and, in some cases, longevity of the module will be reduced. Thus, at times, it is desirable to control the temperature of the modules during operation to achieve optimized efficiency in converting light energy from the sun into electrical energy. It would be desirable to be able to take advantage of heat energy that is produced by the exposure of the solar modules to the sun on a rooftop or other structure and, it would be desirable to have a photovoltaic unit that provides for the safe and aesthetically appealing containment of electrical wires that are used to connect the solar modules.

Thus, there is a need for a photovoltaic module unit that is easily installed. There is a need for a photovoltaic module unit where the photovoltaic module is less prone to damage during shipping and installation. There is a need for a photovoltaic module unit that provides for the aesthetically appealing, simple and safe storage of electrical wires used to connect the modules when the photovoltaic modules are installed. There is also a need for a photovoltaic module unit that can be used to regulate the temperature of the photovoltaic module, and that can be used to gain heat as well as electrical energy. The present invention provides such a photovoltaic module unit.

### SUMMARY OF THE INVENTION

The present invention is a photovoltaic unit suitable for installing on a support structure comprising a photovoltaic module (sometimes also referred to herein as a “solar module”) having a light receiving top side, and a bottom side opposite the top side, and a support substrate comprising a plurality of ridges, for example, at least two ridges, and at least one, and preferably a plurality of troughs, where the support substrate is attached to the bottom side of the module. The present invention is also a photovoltaic unit suitable for installing on a support structure comprising a photovoltaic module having a light receiving top side, and a bottom side opposite the top side, a support substrate attached to the bottom side of the module comprising a plurality of ridges, for example, at least two ridges, at least one and preferably a plurality of troughs, a plurality of first spaces located between the support substrate and the bottom side of the module and between two adjacent ridges, optionally at least one second space located between two adjacent troughs, and at least one conduit positioned within at least one space. The present invention is also a method for manufacturing such photovoltaic module units and a method for installing such photovoltaic units on roofs or other supporting structures. The present invention is useful for generating electrical and, optionally, heat energy from a source of light energy such as the sun.

### BRIEF DESCRIPTION OF THE DRAWINGS

FIG. 1 is a perspective view of a photovoltaic unit in accordance with an embodiment of this invention.

FIG. 2 is a sectional view of the photovoltaic unit of FIG. 1.

FIG. 3 shows various possible shapes of the support substrate useful in embodiments of this invention.

FIG. 4 is a perspective view of a photovoltaic unit in accordance with an embodiment of this invention having conduits positioned in spaces between the supporting substrate and a solar module.

FIG. 5 is a perspective view of a photovoltaic unit in accordance with an embodiment of this invention having a continuous conduit positioned in spaces between the supporting substrate and a solar module.

FIG. 6 is a perspective view of another photovoltaic unit in accordance with an embodiment of this invention.

FIG. 7 is a perspective view of a photovoltaic unit in accordance with an embodiment of this invention.

FIG. 8 is a perspective view of four photovoltaic units in accordance with an embodiment of this invention that are shown mounted on a roof in a shingled, overlapping arrangement.

FIG. 9 is a perspective view of a type of clamp that can be used to attach a photovoltaic module to a support substrate, where the support substrate comprises a plurality of ridges and troughs.

While the invention will be described in connection with its preferred embodiments, it will be understood that this invention is not limited thereto. On the contrary, the invention is intended to cover all alternatives, modifications, and equivalents that may be included within the spirit and scope of the invention.

### DETAILED DESCRIPTION OF THE INVENTION

The present invention is a photovoltaic unit suitable for installing on a support structure, such as a roof, where the unit comprises a photovoltaic module having a light receiving top side, and a bottom side opposite the top side, and a substrate comprising a plurality of ridges, for example, at least two ridges and one or more troughs where the substrate is attached to the bottom side of the module. The present invention is also a unit suitable for installing on a support structure comprising a photovoltaic module having a light receiving top side, and a bottom side opposite the top side, a substrate attached to the bottom side of the module comprising a plurality of ridges, for example, at least two ridges and one or more troughs, a first space or spaces located between the substrate and the bottom side of the module and between two adjacent ridges, and, optionally, a second space or spaces located between two adjacent troughs, and at least one conduit positioned within at least one space.

The photovoltaic module used in the photovoltaic unit of this invention can be any type of photovoltaic module. For example, it can be a module made up of a collection of crystalline or multicrystalline silicon wafers or it can be a thin film module such as thin film module comprising amorphous silicon or comprising cadmium telluride/cadmium sulfide photovoltaic components. Such modules and methods for making such modules are well known to those of skill in the art. Photovoltaic modules are commercially available from a number of manufacturers such as, for example, BP Solar International LLC.

Generally, such photovoltaic modules comprise a first substrate or sheet of transparent material such as plastic or glass. Most modules utilize a sheet of clear glass or other clear material of a convenient size, such as for example about 2 to 3 feet, by about 3 to 5 feet as such first substrate.

In modules that comprise crystalline or multicrystalline phototvoltaic cells, such first substrate or sheet generally forms the light-receiving surface of the module. The photovoltaic cells, arranged in a desired pattern and electrically connected in a desired manner are positioned between the first substrate and a second substrate or sheet of suitable material and typically sealed together using a suitable sealing material, such as, for example, poly ethylene vinyl acetate (EVA) to prevent the ingress of moisture from rain, snow and other forms of atmospheric moisture. The photovoltaic cells are positioned between the first and second substrates with their light receiving, phototvoltaically active surfaces positioned facing the first substrate. The second substrate can be any material that will form a suitable seal to the first substrate and will generally provide some structurally integrity and moisture resistance for the module. Glass can be used although other materials such as sheets of polyvinylfluoride can also be used as the second substrate. Glass, due primarily to its optical properties, cost, and demonstrated excellent performance as a first substrate is the primary material for the first substrate.

The other general type of photovoltaic module is a thin-film module. Methods for manufacturing thin film module are also known in the art. As mentioned above, the thin film element of the module can comprise, for example, amorphous silicon or cadmium telluride/cadmium sulfide thin film photovoltaic elements. Rather than using individual silicon or multicrystalline wafers to construct the photovoltaic module as with the crystalline-type of phototvoltaic modules, the photovoltaic elements of the thin film photovoltaic modules are deposited as thin films on a first substrate. Although a variety of substrates can be used, such as polyvinylfluoride, as with the crystalline and multicrystalline photovoltaic modules, glass in the form of a sheet, is the preferred first substrate. After the thin film elements of the photovoltaic device are deposited on the first substrate, the substrate is generally sealed using an appropriate sealing material, such as EVA, to another substrate to form a sealed module.

Because of the laminated structure of such modules, and particularly when the module is constructed having at least one sheet of glass, it is necessary to use care and caution when the modules are shipped as well as during installation to avoid or reduce the possibility of breakage or damage to the module.

In the phototvoltaic unit of this invention a photovoltaic module is attached to a support substrate where the support substrate comprises a plurality of ridges and at least one and preferably a plurality of troughs. Although not required, the attachment is conveniently accomplished by attaching at least two, and preferably more than two ridges to the module. The support substrate is attached to the bottom side of the module leaving the top, light receiving side uncovered for exposure to, for example, the sun. The support substrate can be in the same general shape as the module to which it to be attached. For example, if the module is rectangular in shape, the support substrate can also be rectangular in shape although it can be of some other shape such as a square shape. The module can be positioned and attached so that it is parallel to the support substrate although it can also be positioned so that it is pitched in one, or even two directions with respect to the support substrate. For example, it can be pitched in such one or two directions at angles of about 1 to about 90 degrees, preferably about 5 to about 50 degrees, and more preferably about 10 to about 45 degrees where such angle is the angle formed between the module and the support substrate. Positioning the module in a pitched manner is useful, for example, at latitudes where, if the unit is mounted on a roof or other pre-existing structure and the support substrate is lying on the roof, the pitched solar module can be disposed so that it is in more directly facing the rays of the sun. The support can be of the same size as the module or it can be larger or smaller than the module. The photovoltaic unit of this invention can comprise one photovoltaic module on each section of support substrate. However, the invention is not limited to one photovoltaic module for each support substrate. Two or more, for example three, four or more photovoltaic modules can be attached to one support substrate.

The support substrate part of the invented unit, as stated above, comprises a plurality or ridges, at least one trough, and preferably a plurality of troughs. For example, the support substrate can be, and preferably is, a section of corrugated material, such as corrugated metal or plastic. The support substrate can be made of galvanized steel or iron, steel, tin, aluminum or other metal or metal alloy. However, it is not necessary for the support substrate to be made of a metal or metal alloy. It can be made of any suitable material, such as a polymeric material or composite material such as a fiberglass reinforced epoxy resins, polyethylene, polypropylene, polystyrene and other polymeric or composite materials. The support substrate can be a laminate of two or more component parts, each part being made of the same material or of different materials. Additionally, the support substrate having such ridges and one or more troughs can have any suitable profile, or edge view. The profile can be a wave-like profile where the ridges and troughs are all rounded. The profile can also have angled ridges and troughs with straight segments between the ridges and troughs. Thus, instead of having rounded ridges and rounded troughs, the tops of the ridges and bottom of the troughs can be angular. The profile can be such that either or both of the ridges and troughs truncated and leveled off. The distance between the top of a ridge and the bottom of the trough can vary. However, it will generally be about 0.5 inch to about 12 inches preferably about 1 inch to about 4 inches. Although, all of the ridges and all of the troughs in the support substrate can be uniform in that they will have the same shape and be of the same size, it is not necessary for them to be uniform. Taking into consideration the material it is constructed of, the support substrate preferably has a thickness that is suitable to provide structure and strength to the unit when it is attached to the photovoltaic module. Generally, the support substrate, and depending on the material the substrate is made from, can have a thickness of about 0.030 to about 0.125 inch. By thickness, we mean the thickness of the material, for example, the metal, polymeric, or composite material, used to make the support substrate or from which the support substrate is made. Thus, if the support substrate is made by bending or otherwise shaping a sheet of metal, such as a sheet of steel, to form the desired ridges and troughs, the thickness of the resulting support substrate would be the thickness or gauge of the steel sheet.

In the unit of this invention the module is attached to the support substrate. In a preferred embodiment, the tops of a plurality of the ridges, for example, at least two of the ridges, of the support substrate are attached to the bottom of a photovoltaic module. The support substrate can be attached to the module by any suitable attachment such as, for example, by a clamp, bracket, bolt, strapping and the like, or by an adhesive. If a clamp, bracket, or bolt, or similar device is used, and particularly where it is made of a metal or other hard material, it is preferable to use a cushion, such as a section of polymeric material or rubbery material, between the clamp, bracket, bolt or similar device and the photovoltaic module and, preferably, also between the support substrate and the photovoltaic module so that metal or other hard material is not pressing against the photovoltaic module. If the module has a frame around all or part of the module, such as a frame made of a metal or a polymeric material, the frame can be attached to the support substrate by any suitable means for attaching the frame to the support substrate such as by one or more of an adhesive, a clamp, bolt, rivet, strapping, screw, and the like. Thus, the frame itself, and only the frame can be attached to the support substrate as a means to attach the bottom side of the module to the support substrate. If the module does not have a frame, the preferred method of attachment is a clamp, bracket and the like, or an adhesive. A suitable adhesive is the preferred method of attachment. Any suitable adhesive can be used that will adhere to the support substrate and the photovoltaic module such as commercially available epoxy adhesives or construction adhesives. While it is preferable for the bottom of the module or, if the module has a frame, the frame, to be positioned next to the support substrate, for example, as close as the adhesive, bracket, clamp or other device will permit, depending on the clamp or other device used to attach the module to the support structure, there can also be a space between the top of the ridges of the support substrate and the bottom of the module.

In the unit of this invention where the support substrate and the module are positioned so that they are in close proximity, for example, where the bottom surface of the module is no more than about 4 inches, more preferably no more than about 1 inch, and most preferably where the bottom surface of the module is attached next to the support structure by adhesive or by a clamp, from the top part of the ridges in the support substrate, and particularly where the module is positioned parallel to the support substrate, there are first spaces located between the bottom of the module and between two adjacent ridges of the support substrate. When the unit is installed for use, such as on a roof or other support structure, such spaces can be used to regulate the temperature of the module, such as withdrawing heat from the module when the module is being heated as a result of being exposed to the sun. For example, air can be passed through such spaces to remove heat from the underside of the module. The movement of air can occur with assistance of a mechanical means such as a blower or fan, or the air can move through such spaces by convection. Thus, the unit of this invention can maintain the module at, for example, a cooler temperature than would otherwise be, by providing for the movement of air through such spaces beneath the module to remove heat from the module. This is particularly useful for modules containing crystalline or multicrystalline silicon wafer cells and where such cell may operate more efficiently at lower temperatures.

In one aspect of this invention, the spaces described above can contain one or more conduits, such as, for example, a tube, or pipe. The conduit can be used to circulate a fluid, such as, for example, air, water, a glycol or mixture of glycol and water, or other suitable fluid that can be used as a heat transfer medium. Thus, the circulating fluid in the conduit can be used to withdraw heat from or add heat to the underside of the module thereby regulating the temperature of the module to a desired temperature or range of temperatures. The heat in the fluid exiting the conduits can be used as a source of energy for any suitable purpose. Thus, the unit of this invention comprising the solar module, conduits and support substrate can be utilized to gain solar energy in the form of electrical energy and also heat energy in the form of a heated fluid. The conduits can also be used to contain electrical wiring used to connect one or more solar modules. The conduits can also pass through one or more second spaces, if present, between two troughs. Such second spaces can also be used for the same purposes as described above for the first spaces when the unit is mounted on a roof or other support structure. Additionally, the conduits passing through one space can be connected in a loop fashion with the conduit in one or more other spaces in a unit. Thus, the conduit can be one continuous conduit looping through a plurality of spaces in a unit. When one or more units are disposed on a roof or other structure, the conduit can loop through one or more spaces of a plurality of units. For example an interconnected or continuous conduit can, for example, loop through a plurality of spaces and through a plurality of photovoltaic units.

The spaces, preferably the first spaces, can be used to contain wiring, for example, wiring used to connect the modules to each other when one or more modules, such as in an array, are used to generate electrical current.

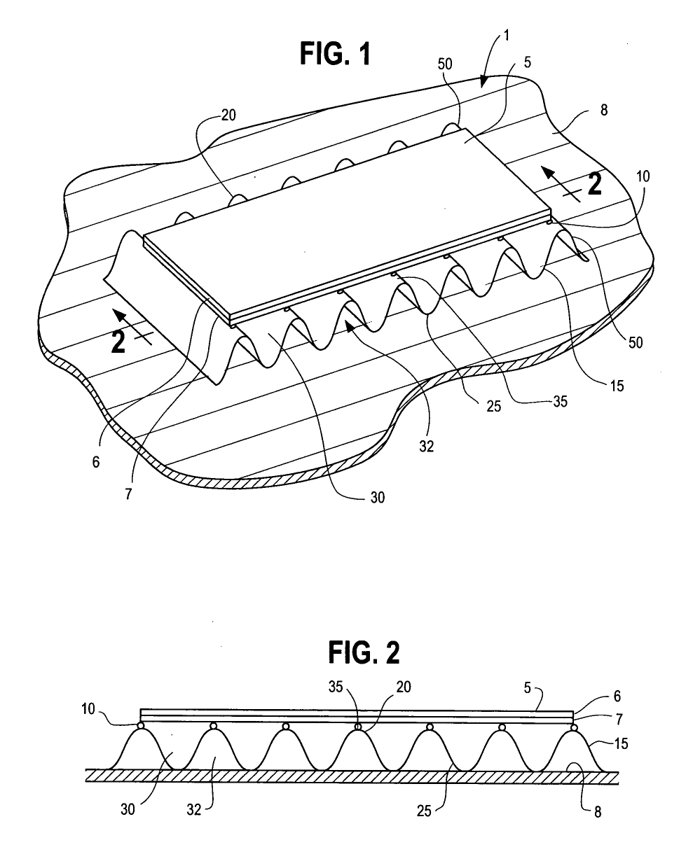

FIGS. 1-9 show embodiments of the present invention but are not intended to limit the scope of the invention.

FIG. 1 is a perspective view of an embodiment of photovoltaic unit 1 of this invention. FIG. 1 shows photovoltaic module 5 on rooftop segment 8, where the module is attached by portions of adhesive 10 to support substrate 15. Support substrate 15 comprises a plurality of ridges 20 and troughs 25. Module 5 is shown having upper glass sheet 6 and lower, for example, glass sheet 7. Laminated between sheets 6 and 7 are the individual solar cells that make up the module. The individual solar cells are not shown in the figure. Adhesive 10 is placed so that the bottom surface of module 5 (bottom surface not visible in the figure) is adhered to the tops 35 of ridges 20. FIG. 1 also shows first spaces 30 located between the bottom surface of the module and between two ridges 20, and it shows second spaces 32 located between troughs 25. (For clarity, only one of each of the ridges, troughs, spaces, tops of ridges, bottom of troughs, and portions of adhesive are numbered in FIG. 1.)

FIG. 2 is the section 2 view from FIG. 1. Elements in FIG. 2 that are the same as in FIG. 1 are numbered the same. FIG. 2 shows portions of adhesive 10 adhering tops 35 of ridges 20 of support substrate 15 to the bottom of sheet 7 of module 5. FIG. 2 also shows the spaces 30 and 32, and troughs 25. As shown in FIGS. 1 and 2 first spaces 30 and second spaces 32 can extend across the entire width of the module. Spaces 30 and 32 are particularly useful because, as will be described in detail below, they can be use to remove heat from the module thereby permitting the regulation of the temperature of the module, and they can be used to collect useful heat energy. (As in FIG. 1, for clarity, only one of each of the ridges, troughs, spaces, tops of ridges, bottom of troughs, and portions of adhesive are numbered in FIG. 2.)

As shown in FIG. 1, the joining, adhering or otherwise attaching the module to the support substrate, particularly where the attaching of the support substrate to the module is at multiple locations or points on the support substrate, results in a sturdy, easily handled unit 1. One or a multiple of such units can be easily positioned on a roof or other supporting structure in a desired pattern, such as in an array of two or more units, with greatly reduced damage to or breakage of the module that would otherwise be caused by, for example, flexing of the module. Where it is desirable during installation of an array comprising two or more units, one unit in the array can be laid over an edge section of another unit having such edge section to form a shingled-type of structure. FIG. 1 only shows edge section 50 along the longer dimension of the rectangular-shaped module 5. However, similar edge section can be formed along the other shorter sides of the rectangular module 5 by using a section of supporting substrate 15 that is longer than the module.

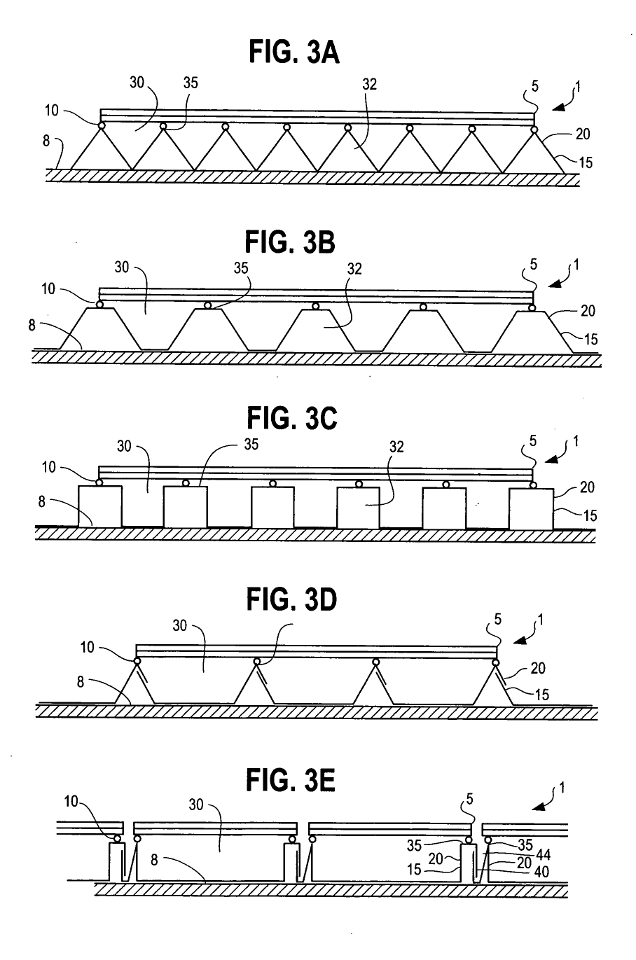

FIG. 3 shows other possible shapes or profiles for the support substrate 15. Each unit 1 shown in FIG. 3 is a side or section view of a photovoltaic unit as shown in FIG. 2. FIG. 3 shows the module 5 attached to supporting substrate 15 by portions of adhesive 10 to tops 35 of ridges 20 thereby forming first spaces 30. Second spaces 32 are also present between adjacent troughs. As shown in A of FIG. 3, the support substrate 15 can have a shape where the tops of the plurality of ridges and the bottoms of the plurality of troughs of the support substrate are angular rather than rounded, they can have a truncated shape as shown in B of FIG. 3, a “squared off” shape as shown in C of FIG. 3, or an overlapping shape as shown in D of FIG. 3. As shown in E of FIG. 3, the support substrate can have a section that forms an interlocking seam with an adjacent support substrate. One such interlocking and, preferably, water proof seam, comprises, as shown in E of FIG. 3, a tab section 40 of support substrate 15 that fits into, and preferably fits tightly into, a slot section 44 of an adjacent support substrate. As shown in E of FIG. 3, there are no other ridges between tab section and the slot section. As shown in E of FIG. 3, the tab and slot sections form ridges, which can be, as shown, attached to the underside or bottom surface of the photovoltaic module. However, there can be additional ridges and additional troughs between such sections. When photovoltaic units of this invention having such interlocking seams are placed on a pitched roof, they are preferably positioned such that the interlocking seem runs up and down along the roof to provide for a waterproof seam between the photovoltaic units. A waterproofing sealant, such as a tar, calk or other sealant, can be applied to the interlocking seam to further provide for a waterproof seam.

The design or shape of the support substrate is not limited to those shown in FIGS. 1 and 3. They can be any shape or design that results in ridges and at least one trough, and preferably a plurality of troughs so that when the support substrate is attached to the module it preferably results in a strong unit that comprise at least one first space 30, and, preferably, first spaces 30 and one or more second spaces 32.

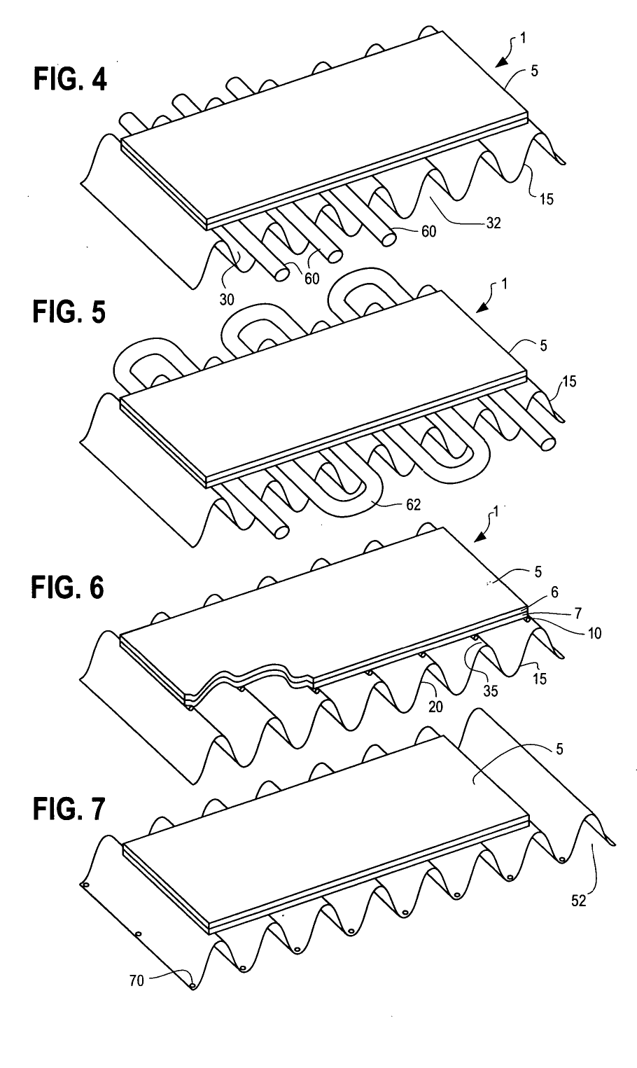

FIG. 4 shows a photovoltaic unit 1 of this invention that is the same as the unit shown in FIG. 1 where photovoltaic module 5 is attached (means of attachment not shown in FIG. 4) to support substrate 15. In the photovoltaic unit shown in FIG. 4, conduits 60 are located within first spaces 30 (for clarity, only one space 30 is labeled in FIG. 4). Although three conduits 60 are shown in FIG. 4, there can be more or less. For example, there can be one conduit for each space 30. Although not shown in FIG. 4, there can be one or more conduits in second spaces 32. The conduits 60 can contain a fluid such as water, a salt/water solution or some other fluid such as a glycol or a glycol/water mixture. There can be more than one conduit in each space 30 or 32. The conduits can have any suitable size and shape. For example, they can have a circular cross-section as shown in FIG. 4, or they can have some other cross-sectional shape. The conduit can be of any suitable diameter or width. For example, the conduits can have a diameter or cross-sectional width that is about 0.5 inches to about 5 inches. The conduits can be made of any suitable material, for example, glass, a polymeric material, a ceramic, or one or more metals. After installation on a roof or other support structure, the conduits, as mentioned above, can have a fluid contained therein or flowing through the conduits. The fluid in the conduits can be used to absorb heat energy that is produced by, for example, the sun when the solar module 5 of the unit is exposed to the sun. The heat energy in the fluid in the conduits can thereafter be utilized as a source of energy by, for example, directing the fluid to a heat exchanger to extract heat energy from the fluid thereby producing a cooled fluid. The cooled fluid, after such heat extraction, can be recycled to the conduits using a pump or other suitable means for returning the cooled fluid to the conduits. Thus, the photovoltaic unit of this invention having the conduits located within one or more of the first spaces 30 or second spaces 32 can be used to gain heat energy from the photovoltaic unit. Such conduits containing a fluid can also be used to control the temperature of the photovoltaic module by removing excess heat from or adding heat to the underside of the module. As mentioned above, some photovoltaic modules, particularly the photovoltaic modules comprising crystalline silicon or multicrystalline crystalline photovoltaic cells, operate more efficiently at converting sunlight into electricity when operated at specific temperatures. Often, such desired temperatures are lower than the temperature the module would attain if heat energy were not removed from the module. In such cases, the photovoltaic unit of this invention containing conduits in one or more of first spaces 30 or second spaces 32, with a fluid circulating within the conduits to remove heat from the underside of the module provides for a photovoltaic module that can be operated at a lower temperature, where such temperature provides for a higher efficiency in converting light energy into the desired electrical energy. Additionally, fluid can be circulated through the conduits to remove heat from a building, such as a house. In such manner, the circulating fluid can be used to cool a house or other structure. Heated fluid can be circulated through the conduits to warm the photovoltaic modules. For example, if the photovoltaic modules are coated with ice or covered with snow, the modules can be heated to melt the ice or snow by circulating a warm fluid through the conduits. In addition to containing fluid, the conduits can be used to hold or contain the electrical wiring that is used to connect one or more of the photovoltaic modules.

FIG. 5 shows a photovoltaic unit 1 of this invention where a conduit 62 is passed through first spaces 30 of photovoltaic unit 1 in a serpentine manner. In such an arrangement, the conduit, which can be of the same dimensions and can be made of the same materials as just describes with respect to conduits 60 in FIG. 4, can be used to efficiently collect or absorb heat energy from or add heat energy to the underside of module 5. Elements or components of photovoltaic module 1 not numbered or otherwise identified in FIGS. 4 and 5 are the same shown and numbered in FIGS. 1-3.

FIG. 6 shows a photovoltaic unit 1 of this invention where photovoltaic module 5, made glass sheets 6 and 7 having photovoltaic cells laminated therebetween (individual photovoltaic cells not shown in figure), is attached by portions of adhesive 10 to support substrate 15. The support substrate 15 is attached to photovoltaic module 5 by portions of adhesive 10 at the tops portion 35 of ridges 20. As shown in FIG. 6, the photovoltaic module 5 is approximately the same size and shape as the support substrate. Such a photovoltaic unit can be easily transported and installed in a manner that greatly reduces the risk of damaging the photovoltaic module 5.

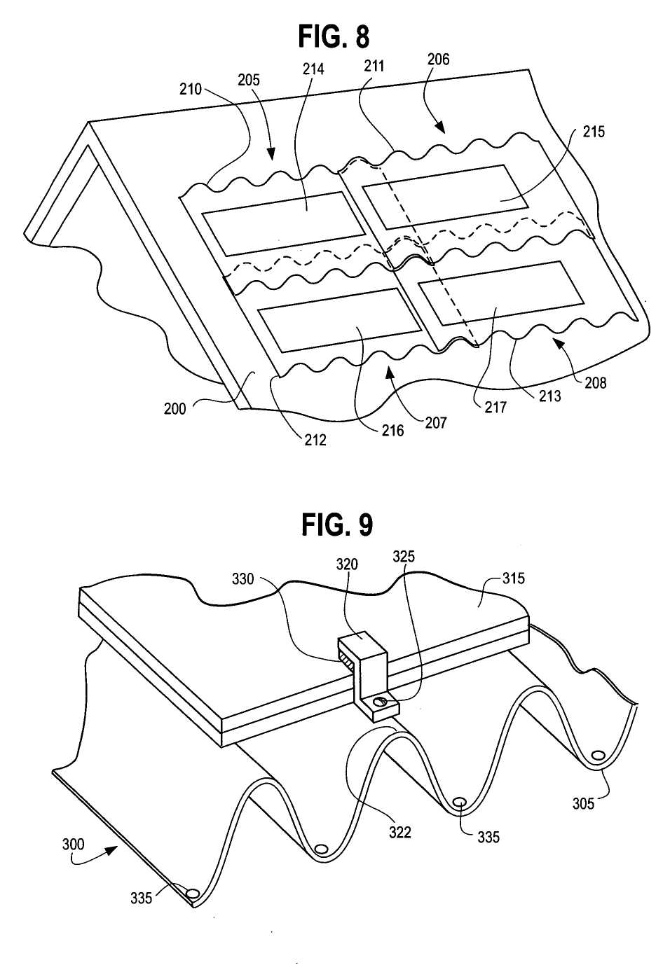

FIG. 7 shows an embodiment of the photovoltaic unit of this invention having a side edge section 52 which can be overlapped by a photovoltaic unit placed adjacent thereto when placed on a roof or other support structure. All other elements shown in FIG. 7 are the same as described for FIG. 1. Holes 70 in support substrate 15 can be used to fasten the unit to a roof or other structure using nails or screws or the like. To simplify the figure, only one of holes 70 is numbered.

FIG. 8 shows four photovoltaic units 205-208 in accordance with an embodiment of this invention positioned as an array on pitched roof 200 in an overlapping manner. Although only four units are shown in the array in FIG. 8, it is to be understood that there can be any number of such units placed on a roof or other support structure in an array or otherwise. As shown in FIG. 8, support substrates 210-213 are attached to modules 214-217, respectively, to form, respectively, the photovoltaic units 205-208. Photovoltaic units 205-208 are placed on roof 200 where one side of upper photovoltaic unit 206 rests on and overlaps an edge section of upper photovoltaic unit 205, and, similarly, corresponding side of lower photovoltaic unit 208 rests on and overlaps edge section of the other lower photovoltaic unit 207. The lower portions of upper photovoltaic units 205 and 206 rest on and overlap upper edge sections of the lower photovoltaic units 207 and 208, thus forming an overlapping, “shingled”-type of waterproof covering for roof 200. This is a configuration where the photovoltaic units of this invention function as both a source of electrical and, optionally, heat energy, as well as the waterproof, uppermost layer of the roof or other structure upon which they are placed.

FIG. 9 shows one suitable means to fasten a photovoltaic module to a support substrate to form the photovoltaic units of this invention. FIG. 9 shows a section of photovoltaic unit 300 having support substrate 305 and photovoltaic module 315. Module 315 is attached to support substrate 305 using a clamp 320. Clamp 320 is attached to the top of a ridge 322 of support substrate 305 by bolt 325 having a slotted head. Between clamp 320 and module 315 is cushion 330. Cushion 330 can be made of, for example, a rubber, either synthetic or natural, or of a polymeric material. Although not shown in FIG. 9, cushion, such as section of cushion as shown in FIG. 9, can be placed between the bottom surface of the module and the support substrate. For simplicity, FIG. 9 shows only one such clamp. It is to be understood, however, that a plurality of such clamps, or other clamps, can be use to attach the module to the support substrate in accordance with this invention. FIG. 9 also shows optional holes 335 that can be used to fasten the photovoltaic module 300 to a rooftop or other support structure by placing a bolt, screw, rivet, nail other such fastener through the hole and into the roof or other support structure.

As mentioned above, the conduits 60 in FIGS. 4 and 62 in FIG. 5 can be used to remove heat from the underside of module when the module is exposed to the sun. However, heat can also be removed by passing air through the spaces 30 and 32 as shown in, for example, FIGS. 1-3. The air can be passed through the spaces by convection or by the use of a fan or blower or other device to force the air through the spaces. When the air is at a lower temperature than the temperature of the bottom of the module, the air, as it passes through the spaces, is heated. Such heated air can be collected at one end of the photovoltaic unit of this invention or at the end of a series of such units arranged in overlapping or edge-to-edge relation. Such heated air is a useful form of energy that can be recovered and used for a number of purposes such as generating heated water for home or commercial use. Additionally, spaces 30 and 32 can contain electrical wiring used to connect the photovoltaic modules or it can be used to contain other components used during the installation of a photovoltaic module or array of photovoltaic modules on a roof or other support structure. For example, such spaces can contain inverters, bypass diodes, batteries and other components. First spaces 30 can be used to contain ballast to hold or assist with holding the unit on a rooftop or other support structure with or without other means to hold the unit on a rooftop or other support structure.

The photovoltaic unit of this invention is preferably constructed prior to installation on a roof or other support structure. Preferably, the unit of this invention comprising the photovoltaic module and the support substrate is constructed at the manufacturing location by attaching or adhering the photovoltaic module to the support substrate by one of the methods described herein or by some other suitable method. The photovoltaic unit can then be shipped to the location of installation with reduced chances of breakage or damage to the photovoltaic module. Thus, the photovoltaic units of this invention having or not having one or more conduits are, preferably, freestanding units and are preferably installed on a roof or other support structure after manufacture or assembly. Conduits, if used, can be part of the unit prior to installation on a roof or other support structure or the conduits can be added after installation.

The photovoltaic units of this invention can be positioned on an existing, waterproof roof. They can be attached by one or more convenient methods such as by inserting nails, screws, bolts, rivets and the like through holes in the support substrate and into the waterproof roof, taking care to make sure any penetrations in the roof are sealed to prevent water leakage. A photovoltaic unit of this invention, and preferably a plurality thereof, can be placed on a roof structure, and attached to the roof structure as described above, to form an uppermost, waterproof covering on a roof structure. The photovoltaic units of this invention would thus serve the dual purpose of being the waterproof covering or surface on a roof, preferably a pitched roof, and a source of electrical and, optionally heat energy.

Provisional Patent Application 60/529,799 filed on Dec. 16, 2003, is hereby incorporated by reference in its entirety.

1. A photovoltaic unit suitable for installing on a support structure comprising a photovoltaic module having a light receiving top side, and a bottom side opposite the top side, and a support substrate attached to the bottom side of the module, the support substrate comprising a plurality of ridges and at least one trough.

2. The unit of claim 1 wherein the ridges have a top portion and the top portion of at least two of the ridges are attached to the module.

3. The unit of claim 2 wherein the top portion of at least two of the ridges are attached to the bottom side of the module.

4. The unit of claim 1 further comprising a frame around the module and wherein the support substrate is attached to the bottom side of the module by at least the frame.

5. The unit of claim 1 further comprising a clamp to clamp the module to the support structure.

6. The unit of claim 1 wherein the bottom side of the photovoltaic module is placed against the support substrate.

7. The unit of claim 1 wherein the photovoltaic module is spaced away from the support substrate.

8. The unit of claim 7 wherein the photovoltaic module is parallel to the support substrate.

9. The unit of claim 1 wherein the photovoltaic module is attached to the support substrate by an adhesive.

10. The unit of claim 1 comprising at least one clamp.

11. A photovoltaic unit comprising:
a photovoltaic module having a light receiving top side, and a bottom side opposite the top side,
a support substrate attached to the bottom side of the module where the support substrate comprising a plurality of ridges and at least one trough,
one or more first spaces located between the support substrate and the bottom side of the module and between two adjacent ridges, and at least one conduit in at least one first space.

12. The photovoltaic unit of claim 11 wherein the conduit contains a fluid.

13. The photovoltaic unit of claim 11 wherein the conduit contains electrical wiring.

14. The photovoltaic unit of claim 11 wherein the conduit passes through a plurality of spaces.

15. The photovoltaic unit of claim 1 wherein the support substrate is larger than the photovoltaic module and the unit comprise an edge section corresponding to the portion of the support substrate extending beyond the module.

16. An array positioned on a support structure comprising the photovoltaic units of claim 1.

17. The array of claim 16 wherein the support structure is a roof.

18. The array of claim 16 where the roof is a pitched roof.

19. A method for mounting a photovoltaic module on a support structure comprising attaching a support substrate to a bottom side of a photovoltaic module where the support substrate comprises a plurality of ridges and at least one trough to form a photovoltaic unit, and thereafter placing the unit on a support structure.

20. The method of claim 19 wherein the support structure is a roof.

21. The method of claim 19 wherein a plurality of units are placed on the support structure.

22. The method of claim 21 wherein the photovoltaic units are placed on the support structure in the form of an array having at least two photovoltaic units.

23. The method of claim 22 wherein the support substrate is larger than the photovoltaic module and the photovoltaic unit comprises at least one edge section corresponding to a portion of the support substrate extending beyond the module in the photovoltaic unit and wherein at least one unit is positioned in the array so that it overlays the edge section of an adjacent photovoltaic unit in the array.

24. A method for regulating the temperature of a photovoltaic module comprising attaching a bottom side of a photovoltaic module to a support substrate, the support substrate comprising a plurality of ridges and at least one trough, thereby forming a first space between two adjacent ridges, and passing air through at least one first space to remove heat from or add heat to the module and thereby regulating the temperature of the module to a desired temperature.

25. A method for regulating the temperature of a photovoltaic module comprising attaching a bottom side of a photovoltaic module to a support substrate, the support substrate comprising a plurality of ridges and at least one trough, thereby forming a first space between two adjacent ridges, and passing a fluid through conduits positioned in at least one first space whereby the fluid removes or adds heat to the first space and thereby regulating the temperature of the module to a desired temperature.

26. A system for generating electrical energy from solar energy comprising one or more photovoltaic units where each photovoltaic unit comprises a photovoltaic module having a light receiving top side, and a bottom side opposite the top side, a substrate attached to the bottom side of the module, the substrate comprising a plurality of ridges and at least one trough.

27. A method for obtaining heat energy from a photovoltaic module comprising attaching a bottom side of a photovoltaic module to a support substrate, the support substrate comprising a plurality of ridges and at least one trough, thereby forming a first space between two adjacent ridges, and passing air through at least one first space to remove heat from the module and thereby increasing the temperature of the air and forming air having higher heat energy.

28. The method for obtaining heat energy from a photovoltaic module comprising attaching a bottom side of a photovoltaic module to a support substrate, the support substrate comprising a plurality of ridges and at least one trough, thereby forming a first space between two adjacent ridges, and passing a fluid through at least one conduit positioned in at least one first space whereby the fluid removes heat from the module thereby increasing the temperature of the fluid and forming fluid having higher heat energy.

29. The method of claim 19 wherein the unit comprises a waterproof layer for the support structure.
